(19) United States
(12) Patent Application Publication
(10) Pub. No.: US 2023/0230981 A1
(43) Pub. Date: Jul. 20, 2023

(54) SEMICONDUCTOR STRUCTURE AND MANUFACTURING METHOD THEREOF

(71) Applicant: CHANGXIN MEMORY TECHNOLOGIES, INC,, Hefei City (CN)

(72) Inventor: ChihCheng LIU, Hefei City (CN)

(21) Appl. No.: 17/663,531

(22) Filed: May 16, 2022

Related U.S. Application Data
(63) Continuation of application No. PCT/CN2022/080312, filed on Mar. 11, 2022.

(30) Foreign Application Priority Data
Jan. 18, 2022 (CN) 202210055855.9

(51) Int. Cl. H01L 27/12

(52) U.S. Cl. CPC H01L 27/1244; H01L 27/1259

(57) ABSTRACT

The present disclosure relates to a semiconductor structure and a manufacturing method thereof. The semiconductor structure includes: a substrate, including a first region and a second region that are adjacent to each other; an array structure, located on a surface of the substrate and on the first region; a conductive layer, located on a side of the array structure that is away from the substrate and electrically connected to the array structure; a wiring structure, located on a side of the conductive layer that is away from the array structure, where the wiring structure includes a re-wiring through hole, and the re-wiring through hole is electrically connected to the conductive layer; and a first dielectric layer, covering a surface of the second region of the substrate.

### CROSS-REFERENCE TO RELATED APPLICATIONS

This is a continuation of International Patent Application No. PCT/CN2022/080312, filed on Mar. 11, 2022, which claims the priority to Chinese Patent Application 202210055855.9, titled “SEMICONDUCTOR STRUCTURE AND MANUFACTURING METHOD THEREOF” and filed on Jan. 18, 2022. The entire contents of International Patent Application No. PCT/CN2022/080312 and Chinese Patent Application 202210055855.9 are incorporated herein by reference.

### TECHNICAL FIELD

The present disclosure relates to the technical field of semiconductors, and in particular to a semiconductor structure and a manufacturing method thereof.

### BACKGROUND

In the technical field of semiconductors, in order to obtain individual semiconductor structures, process steps are generally as follows: first manufacturing a wafer consisting of a plurality of semiconductor structures, and then cutting the wafer along a scribe line recess between two adjacent semiconductor structures to obtain individual semiconductor structures.

However, after the wafer is cut along the scribe line recess between two adjacent semiconductor structures, metal residues are generated in the semiconductor structures, which leads to the problem of short circuit or discharge in the semiconductor structures formed after cutting.

It should be noted that the information disclosed above is merely intended to facilitate a better understanding of the background of the present disclosure, and therefore may include information that does not constitute the prior art known to those of ordinary skill in the art.

### SUMMARY

According to an aspect of the present disclosure, a semiconductor structure is provided, including:

a substrate, including a first region and a second region that are adjacent to each other;

an array structure, located on a surface of the substrate and on the first region;

a conductive layer, located on a side of the array structure that is away from the substrate, and electrically connected to the array structure;

a wiring structure, located on a side of the conductive layer that is away from the array structure, where the wiring structure includes a re-wiring through hole, and the re-wiring through hole is electrically connected to the conductive layer; and

a first dielectric layer, covering a surface of the second region of the substrate, where a surface of the first dielectric layer that is away from the substrate is closer to the substrate, compared to a surface of the conductive layer that is away from the substrate.

According to an aspect of the present disclosure, the present disclosure provides a method of manufacturing a semiconductor structure. The method of manufacturing a semiconductor structure includes:

forming a substrate, where the substrate includes a first region and a second region that are adjacent to each other;

forming an array structure on a surface of the substrate, where the array structure is located on the first region;

forming a conductive layer on a side of the array structure that is away from the substrate, where the conductive layer is electrically connected to the array structure;

forming a wiring structure on a side of the conductive layer that is away from the array structure, where the wiring structure includes a re-wiring through hole, and the re-wiring through hole is electrically connected to the conductive layer; and

forming a first dielectric layer covering a surface of the second region, where a surface of the first dielectric layer that is away from the substrate is closer to the substrate, compared to a surface of the conductive layer that is away from the substrate.

### BRIEF DESCRIPTION OF THE DRAWINGS

The accompanying drawings incorporated into the specification and constituting part of the specification illustrate the embodiments of the present disclosure, and serve, together with the specification, to explain the principles of the present disclosure. Apparently, the drawings in the following description show merely some embodiments of the present disclosure, and those of ordinary skill in the art may still derive other drawings from these drawings without creative efforts.

FIG. 1 is a schematic structural diagram of a semiconductor structure according to an implementation of the present disclosure;

FIG. 2 is a schematic structural diagram of a semiconductor structure according to another implementation of the present disclosure;

FIG. 3 is a schematic flowchart of a method of manufacturing a semiconductor structure according to an implementation of the present disclosure; and

FIG. 4 to FIG. 15 are schematic structural flowcharts of a method of manufacturing a semiconductor structure according to an implementation of the present disclosure.

### DETAILED DESCRIPTION

The exemplary implementations are described more comprehensively below with reference to the accompanying drawings. However, the exemplary implementations may be implemented in various forms, and may not be construed as being limited to those described herein. On the contrary, these implementations are provided to make the present disclosure comprehensive and complete and to fully convey the concept of the exemplary implementations to those skilled in the art. The same reference numerals in the figures indicate the same or similar structures, and thus their detailed descriptions are omitted.

In addition, in the detailed description below, for ease of explanation, many specific details are illustrated to provide a comprehensive understanding of the embodiments of the present disclosure. However, it is obvious that one or more embodiments can also be implemented without the specific details.

It should be noted that, the terms “on”, “formed on” and “provided on” may represent that one layer is directly formed or provided on another layer, or one layer is indirectly formed or provided on another layer, that is, another layer exists between two layers.

The terms “one”, “a”, “the”, “said”, and “at least one” are used to indicate the presence of one or more elements/components/and the like; the terms “includes” and “has” are used to indicate an open-ended inclusion and to mean that additional elements/components/and the like may exist in addition to the listed elements/components/and the like.

It should be noted that although terms such as “first” and “second” may be used to describe various parts, components, elements, regions, layers and/or sections, these parts, components, elements, regions, layers and/or sections should not be limited by these terms. Instead, these terms are merely intended to distinguish one part, component, element, region, layer and/or section from another.

In the present disclosure, unless otherwise specified, the term “provided in the same layer” means that two layers, parts, components, elements, or sections may be formed through a same composition process, and the two layers, parts, components, elements, or sections are generally made of a same material.

According to an aspect of the present disclosure, a semiconductor structure is provided. The semiconductor structure can avoid the problem of metal residuals generated on the semiconductor structure due to an excessive thickness of the semiconductor structure during cutting along a scribe line recess, thereby avoiding the problem of short circuit or discharge of the semiconductor structure in the subsequent use process.

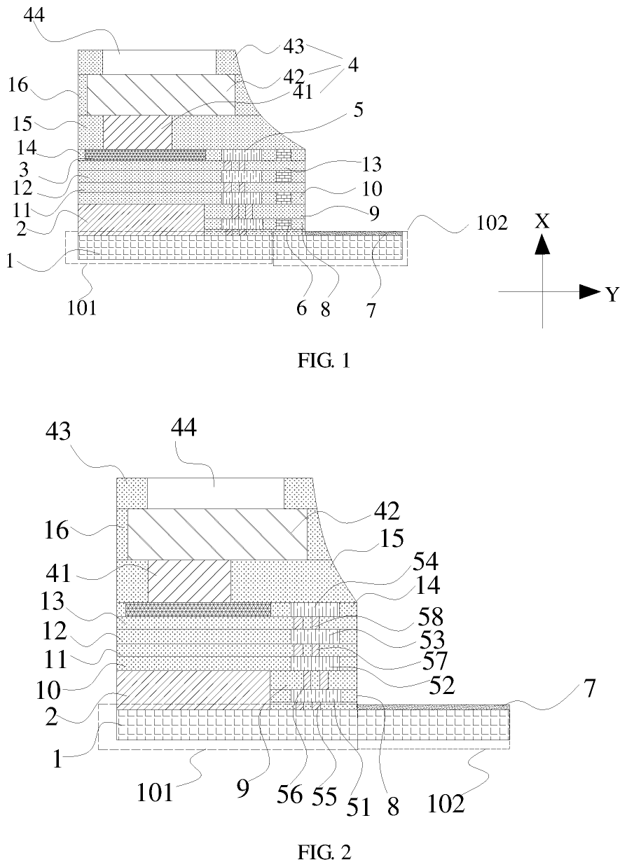

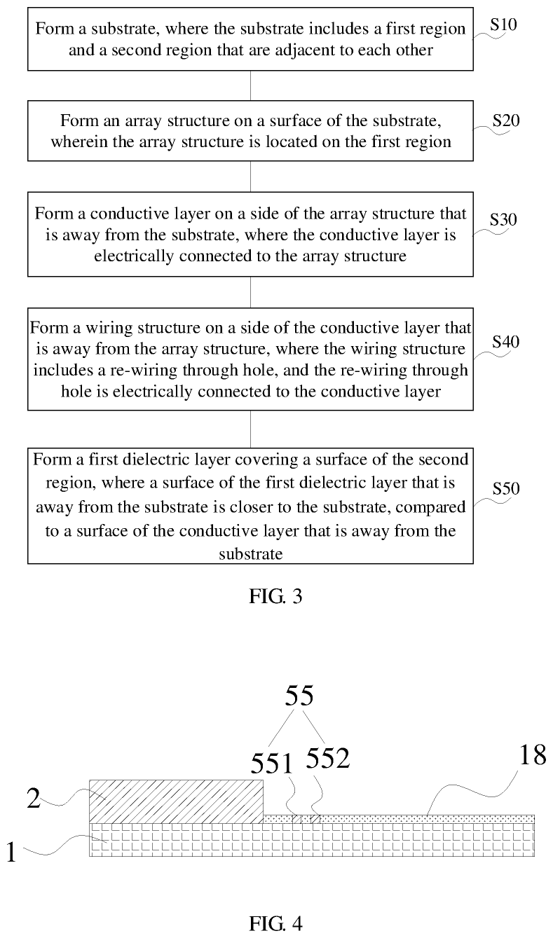

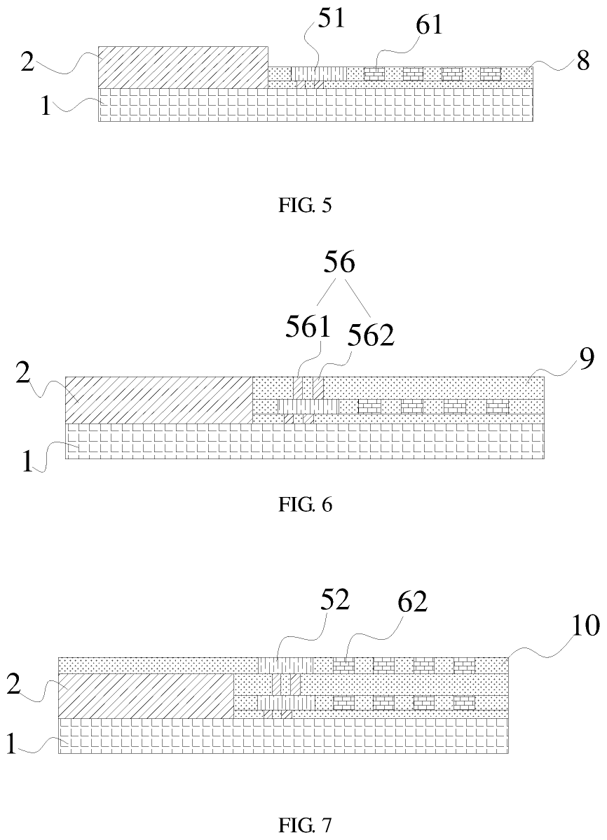

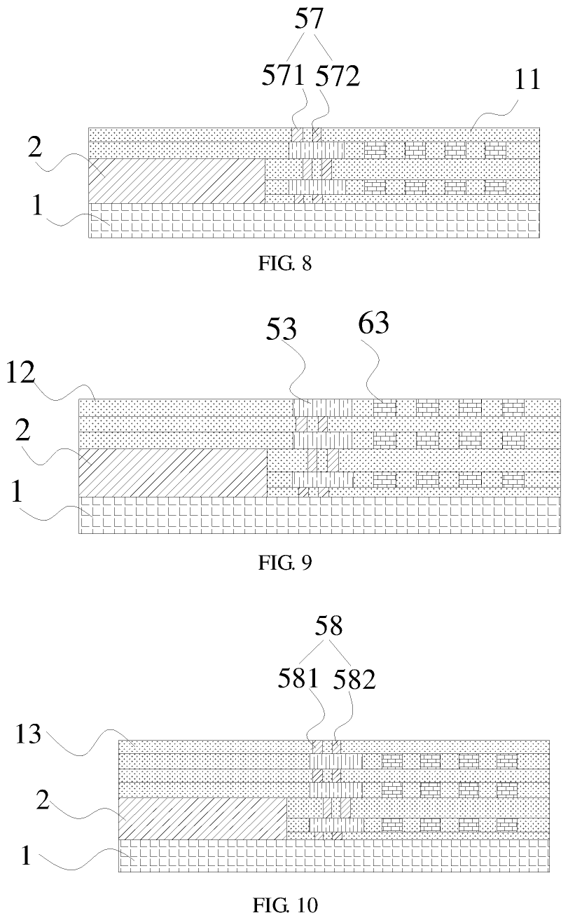

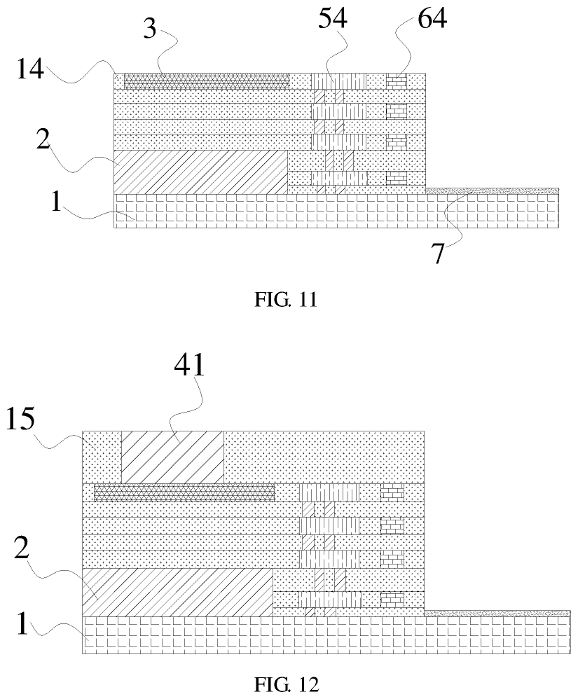

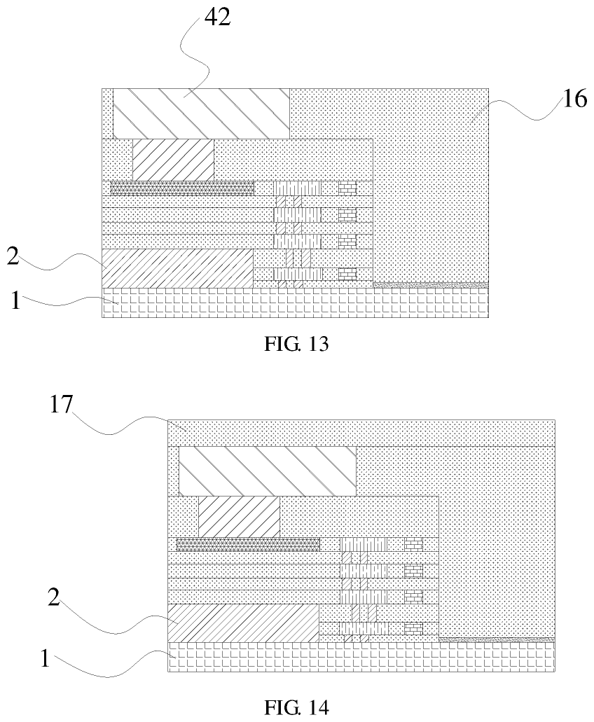

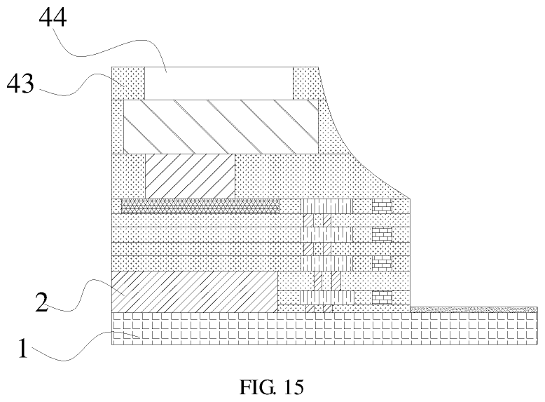

As shown in FIG. 1, FIG. 2, and FIG. 4 to FIG. 15, the semiconductor structure provided by the present disclosure may include: a substrate 1, an array structure 2, a conductive layer 3, a wiring structure 4, and a first dielectric layer 7. The substrate 1 may include a first region 101 and a second region 102 adjacent to each other. The first region 101 may be provided with a scribe line recess at a side away from the second region 102, and the second region 102 may also be provided with a scribe line recess at a side away from the first region 101. It may be understood that, in an uncut wafer, in two adjacent semiconductor structures, the second region 102 of the semiconductor structure may be adjacent to the first region 101 of the semiconductor structure, and a scribe line recess is provided between the second region 102 of the semiconductor structure and the first region 101 of the second semiconductor structure. When individual semiconductor structures need to be obtained, it is necessary to cut along the scribe line recess, to separate two adjacent semiconductor structures.

In the substrate 1, a word line structure, a bit line structure, and a shallow trench isolation structure may be provided. The word line structure and the bit line structure may be located in the first region 101 of the substrate 1, so as to be electrically connected to the array structure 2. The shallow trench isolation structure may be located in the first region 101 and/or the second region 102. However, the present disclosure is not limited thereto. A word line structure and a bit line structure may also be provided in the second region 102 of the substrate 1, which may be configured according to actual needs, and all such configurations fall within the protection scope of the present disclosure.

The array structure 2 may be located on a surface of the substrate 1, and is located on the first region 101. The array structure 2 may be electrically connected to the bit line structure and the word line structure, to receive electrical signals sent by the word line structure and the bit line structure. In an embodiment of the present disclosure, the array structure 2 may be a capacitor contact structure. However, the present disclosure is not limited thereto. The array structure 2 may further include other array elements, which may be configured according to actual needs, and all such configurations fall within the protection scope of the present disclosure.

The conductive layer 3 may be located on a side of the array structure 2 that is away from the substrate 1 and electrically connected to the array structure 2, to transfer an electrical signal sent by the array structure 2. In an embodiment of the present disclosure, the conductive layer 3 may be made of a metal material, such as tungsten, which may be selected according to actual needs.

The wiring structure 4 may be located on a side of the conductive layer 3 that is away from the array structure 2. The wiring structure 4 may include: a re-wiring through hole 41, a re-wiring layer 42, and a passivation layer 43. The re-wiring through hole 41 may be located on a surface of the conductive layer 3 that is away from the array structure 2 and electrically connected to the conductive layer 3. Therefore, the re-wiring through hole 41 provided by the present disclosure may be electrically connected to the array structure 2 through the conductive layer 3.

The re-wiring layer 42 may be located on a side of the re-wiring through hole 41 that is away from the substrate 1, and the re-wiring layer 42 may be electrically connected to the re-wiring through hole 41, so as to be electrically connected to the array structure 2 through the re-wiring through hole 41 and the conductive layer 3. The thickness of the re-wiring layer 42 may be greater than or equal to 5 μm, but is not limited thereto. The thickness of the re-wiring layer 42 may also be less than 5 μm.

The passivation layer 43 may be located on a side of the re-wiring layer 42 that is away from the substrate 1 to protect the re-wiring layer 42, thereby preventing the re-wiring layer 42 from being damaged. Meanwhile, to enable the re-wiring layer 42 to be connected to other elements, the passivation layer 43 may be provided with an opening 44. An orthographic projection of the opening 44 on the substrate 1 may be located in an orthographic projection of the conductive layer 3 on the substrate 1. It may be understood that, the passivation layer 43 may be located on a side of the re-wiring layer 42 that is away from the substrate 1, and is located at the edge of the re-wiring layer 42, so that a middle part of the re-wiring layer 42 is exposed to be connected to other external elements or structures.

In an embodiment of the present disclosure, the passivation layer 43 may be made of silicon dioxide, but is not limited thereto. The passivation layer 43 may also be made of silicon nitride or the like, and any material that makes the passivation layer 43 insulated and have a protection function falls within the protection scope of the present disclosure.

In an embodiment of the present disclosure, the conductive layer 3, the re-wiring through hole 41, the re-wiring layer 42, and the passivation layer 43 may all be located on the first region 101. It may be understood that, projections of the conductive layer 3, the re-wiring through hole 41, the re-wiring layer 42, and the passivation layer 43 on the substrate 1 are only located on the first region 101 of the substrate 1, but do not overlap with the second region 102 of the substrate 1.

The first dielectric layer 7 may cover a surface of the second region 102 of the substrate 1. In other words, a side of the first dielectric layer 7 that is away from the first region 101 may be adjacent to a scribe line recess used during cutting. In addition, a surface of the first dielectric layer 7 that is away from the substrate 1 is closer to the substrate 1, compared to a surface of the conductive layer 3 that is away from the substrate 1. Moreover, the first dielectric layer 7 may not be provided with other layer structures in a region close to the scribe line region. It may be understood that, only the first dielectric layer 7 is provided in a partial area of the second region 102 that is away from the first region 101.

Therefore, the first dielectric layer 7 provided by the present disclosure is at a lower height than the conductive layer 3. In this way, the present disclosure can reduce the thickness during cutting of the semiconductor structure along the scribe line recess and thus avoid the problem of metal residuals generated during cutting due to the excessive thickness of the semiconductor structure during cutting, thereby avoiding the problem of short circuit or discharge of the semiconductor structure in the subsequent use process.

In an embodiment of the present disclosure, a surface of the first dielectric layer 7 that is away from the substrate 1 may be closer to the substrate 1, compared to a surface of the array structure 2 that is away from the substrate 1. Therefore, the first dielectric layer 7 is at a lower height than the array structure 2. In this way, by setting a surface of the first dielectric layer 7 that is away from the substrate 1 to be closer to the substrate 1, compared to a surface of the array structure 2 that is away from the substrate 1, the thickness of the first dielectric layer 7 may further be reduced, thereby further reducing the thickness of the semiconductor structure during cutting along the scribe line recess, so as to further reduce the probability of generating metal residuals during cutting of the semiconductor structure. Therefore, the problem of short circuit or discharge of the semiconductor structure in the subsequent use process can be prevented.

In an embodiment of the present disclosure, a thickness of the first dielectric layer 7 may be greater than or equal to 10 nm. By setting the thickness of the first dielectric layer 7 to be greater than 10 nm, the first dielectric layer 7 can provide a better insulation and protection function for the substrate 1, to prevent exposure of the substrate 1 due to an insufficient thickness of the first dielectric layer 7.

In an embodiment of the present disclosure, the first dielectric layer 7 may be made of silicon dioxide, but is not limited thereto. The first dielectric layer 7 may also be made of silicon nitride or the like, which may be selected according to actual needs, and all such materials fall within the protection scope of the present disclosure.

In an embodiment of the present disclosure, the semiconductor structure may further include:

a protection structure 5. The protection structure 5 may be located on the first region 101, and may be located between the array structure 2 and the first dielectric layer 7. The protective layer can prevent moisture from entering the array structure 2 and the wiring structure 4, and can also prevent the array structure 2 and the wiring structure 4 from being damaged due to stress during cutting of the semiconductor structure.

In an embodiment of the present disclosure, a surface of the protection structure 5 that is away from the substrate 1 may be farther away from the substrate 1, compared to a surface of the first dielectric layer 7 that is away from the substrate 1. In other words, it may be understood that the protection structure 5 is located at a higher position than the first dielectric layer 7.

In addition, a distance between the substrate 1 and a surface of the protection structure 5 that is away from the substrate 1 is the same as a distance between the substrate 1 and a surface of the conductive layer 3 that is away from the substrate 1. It may be understood that, a surface of the protection structure 5 that is away from the substrate 1 may be at the same height as a surface of the conductive layer 3 that is away from the substrate 1.

In an embodiment of the present disclosure, the protection structure 5 may include: a plurality of protective layers. The protective layers may be arranged at intervals along a first direction X, and adjacent protective layers may be connected to each other. Moreover, a protective layer that is close to the substrate 1 among the plurality of protective layers may be connected to the substrate 1.

In the present disclosure, when a plurality of protective layers are provided, a protective layer away from the substrate 1 among the plurality of protective layers may be provided in the same layer with the conductive layer 3. That is, in the protective layer away from the substrate 1 among the plurality of protective layers, a distance between the substrate 1 and a surface that is away from the substrate 1 is the same as a distance between the substrate 1 and a surface of the conductive layer 3 that is away from the substrate 1, and the thickness of the protective layer away from the substrate 1 among the plurality of protective layers may be the same as that of the conductive layer 3.

In an embodiment of the present disclosure, the protection structure 5 may at least include: a first protective layer 51, a second protective layer 52, a third protective layer 53, and a fourth protective layer 54 that are arranged at intervals along the first direction X. The semiconductor structure provided by the present disclosure may further include: a second dielectric layer 8, a third dielectric layer 9, a fourth dielectric layer 10, a fifth dielectric layer 11, a sixth dielectric layer 12, a seventh dielectric layer 13, and an eighth dielectric layer 14 that are sequentially formed along the first direction X on the first region 101.

The first protective layer 51 may be located in the second dielectric layer 8; the second protective layer 52 may be located in the fourth dielectric layer 10; the third protective layer 53 may be located in the sixth dielectric layer 12; the fourth protective layer 54 may be located in the eighth dielectric layer 14.

In an embodiment of the present disclosure, the protective layer away from the substrate 1 among the plurality of protective layers may be provided in the same layer with the conductive layer 3. Therefore, the fourth protective layer 54 may be provided in the same layer with the conductive layer 3. That is, both the fourth protective layer 54 and the conductive layer 3 may be provided in the eighth dielectric layer 14. Moreover, the fourth protective layer 54 and the conductive layer 3 may be formed in the same step, but the present disclosure is not limited thereto. The fourth protective layer 54 and the conductive layer 3 may alternatively be formed in different steps. For example, the conductive layer 3 may be formed in the eighth dielectric layer 14 first, and then the fourth protective layer 54 and so on may be formed in the eighth dielectric layer 14. All these approaches fall within the protection scope of the present disclosure.

In an embodiment of the present disclosure, the first protective layer 51, the second protective layer 52, the third protective layer 53, and the fourth protective layer 54 may be made of a metal material, such as tungsten. The present disclosure does not limit the specific material of the first protective layer 51, the second protective layer 52, the third protective layer 53, and the fourth protective layer 54, so along as the material is a metal material, and any metal material selected according to actual needs can fall within the protection scope of the present disclosure.

In an embodiment of the present disclosure, the protection structure 5 may further include: a first connection layer 55, a second connection layer 56, a third connection layer 57, and a fourth connection layer 58. The first connection layer 55 may be located between the first protective layer 51 and the substrate 1 to connect the first protective layer 51 and the substrate 1. The second connection layer 56 may be located between the second protective layer 52 and the first protective layer 51 to connect the second protective layer 52 and the first protective layer 51. The third connection layer 57 may be located between the third protective layer 53 and the second protective layer 52 to connect the third protective layer 53 and the second protective layer 52. The fourth connection layer 58 may be located between the fourth protective layer 54 and the third protective layer 53 to connect the fourth protective layer 54 and the third protective layer 53.

A dielectric layer may also be provided between the first protective layer 51 and the substrate 1, and the first connection layer 55 may be located in the dielectric layer. The second connection layer 56 may be located in the third dielectric layer 9; the third connection layer 57 may be located in the fifth dielectric layer 11; the fourth connection layer 58 may be located in the seventh dielectric layer 13.

In an embodiment of the present disclosure, a projection of the first connection layer 55 on the substrate 1 may be located inside a projection of the first protective layer 51 on the substrate 1. A projection of the second connection layer 56 on the substrate 1 may be located inside a projection of the second protective layer 52 on the substrate 1. A projection of the third connection layer 57 on the substrate 1 may be located inside a projection of the third protective layer 53 on the substrate 1. A projection of the fourth connection layer 58 on the substrate 1 may be located inside a projection of the fourth protective layer 54 on the substrate 1.

The first connection layer 55 may include a first connection pillar 551 and a second connection pillar 552 that may be spaced apart from each other. The second connection layer 56 may include a third connection pillar 561 and a fourth connection pillar 562 that may be spaced apart from each other. The third connection layer 57 may include a fifth connection pillar 571 and a sixth connection pillar 572 that may be spaced apart from each other. The fourth connection layer 58 may include a seventh connection pillar 581 and an eighth connection pillar 582 that may be spaced apart from each other.

In an embodiment of the present disclosure, the first connection layer 55 and the second connection layer 56 may be arranged in a staggered manner; the second connection layer 56 and the third connection layer 57 may be arranged in a staggered manner; the third connection layer 57 and the fourth connection layer 58 may be arranged in a staggered manner.

It may be understood that, a projection of the third connection pillar 561 of the second connection layer 56 on the substrate 1 may be located between projections of the first connection pillar 551 and the second connection pillar 552 on the substrate 1. Moreover, the projection of the second connection pillar 552 of the first connection layer 55 on the substrate 1 may be located between projections of the third connection pillar 561 and the fourth connection pillar 562 on the substrate 1. A projection of the sixth connection pillar 572 of the third connection layer 57 on the substrate 1 may be located between projections of the third connection pillar 561 and the fourth connection pillar 562 on the substrate 1, and the projection of the sixth connection pillar 572 on the substrate 1 may be located between projections of the seventh connection pillar 581 and the eighth connection pillar 582 on the substrate 1. The projection of the seventh connection pillar 581 of the fourth connection layer 58 on the substrate 1 may be located between projections of the fifth connection pillar 571 and the sixth connection pillar 572 on the substrate 1.

As shown in FIG. 1, in an embodiment of the present disclosure, the semiconductor structure may further include a dummy pattern group. The dummy pattern group may be located between the protection structure 5 and the first dielectric layer 7, and a surface of the dummy pattern group that is away from the substrate 1 is farther away from the substrate 1, compared to a surface of the first dielectric layer 7 that is away from the substrate 1. It may be understood that, the surface of the dummy pattern group that is away from the substrate 1 is located at a higher position than the first dielectric layer 7.

The dummy pattern group may include a plurality of dummy pattern layers 6. The plurality of dummy pattern layers 6 may be arranged along the first direction X at intervals, and a projection of each dummy pattern layer 6 on a second direction Y may overlap with the projection of one protective layer on the second direction Y. The second direction Y may be a direction pointing from the dummy pattern group to the protection structure 5.

In an embodiment of the present disclosure, the projection of each dummy pattern layer 6 on the second direction Y coincides with the projection of one protective layer on the second direction Y. That is, each dummy pattern layer 6 may be provided in a same layer with one protective layer. Therefore, the dummy pattern layer 6 and the protective layer may be formed in the same process step.

In an embodiment of the present disclosure, the dummy pattern layer 6 may be made of a metal material, such as tungsten, but is not limited thereto. Moreover, the conductive layer 3, the protective layer, and the dummy pattern layer 6 may be made of a same material.

In an embodiment of the present disclosure, a part of the second region 102 is also provided with the second dielectric layer 8, the third dielectric layer 9, the fourth dielectric layer 10, the fifth dielectric layer 11, the sixth dielectric layer 12, the seventh dielectric layer 13, and the eighth dielectric layer 14. In addition, the second dielectric layer 8 on the second region 102 may also be located on a surface of the first dielectric layer 7, connected to the second dielectric layer 8 on the first region 101, and provided in a same layer with the second dielectric layer 8 on the first region 101. The third dielectric layer 9 on the second region 102 may be connected to the third dielectric layer 9 on the first region 101, and provided in a same layer with the third dielectric layer 9 on the first region 101. The fourth dielectric layer 10 on the second region 102 may be connected to the fourth dielectric layer 10 on the first region 101, and provided in a same layer with the fourth dielectric layer 10 on the first region 101. The fifth dielectric layer 11 on the second region 102 may be connected to the fifth dielectric layer 11 on the first region 101, and provided in a same layer with the fifth dielectric layer 11 on the first region 101. The sixth dielectric layer 12 on the second region 102 may be connected to a sixth dielectric layer 12 on the first region 101, and provided in a same layer with the sixth dielectric layer 12 on the first region 101. The seventh dielectric layer 13 on the second region 102 may be connected to the seventh dielectric layer 13 on the first region 101, and provided in a same layer with the seventh dielectric layer 13 on the first region 101. The eighth dielectric layer 14 on the second region 102 may be connected to the eighth dielectric layer 14 on the first region 101, and provided in a same layer with the eighth dielectric layer 14 on the first region 101.

The dummy pattern layer 6 at least includes: a first pattern layer 61, a second pattern layer 62, a third pattern layer 63, and a fourth pattern layer 64. The first pattern layer 61 may be located in the second dielectric layer 8 of the second region 102; the second pattern layer 62 may be located in the fourth dielectric layer 10 of the second region 102; the third pattern layer 63 may be located in the sixth dielectric layer 12 of the second region 102; the fourth pattern layer 64 may be located in the eighth dielectric layer 14 of the second region 102.

In an embodiment of the present disclosure, a projection of the first pattern layer 61 on the second direction Y may overlap with a projection of the first protective layer 51 on the second direction Y. A projection of the second pattern layer 62 on the second direction Y may overlap with a projection of the second protective layer 52 on the second direction Y. A projection of the third pattern layer 63 on the second direction Y may overlap with a projection of the third protective layer 53 on the second direction Y. A projection of the fourth pattern layer 64 on the second direction Y may overlap with a projection of the fourth protective layer 54 on the second direction Y.

Moreover, in an embodiment of the present disclosure, the projection of the first pattern layer 61 on the second direction Y may coincide with the projection of the first protective layer 51 on the second direction Y; the projection of the second pattern layer 62 on the second direction Y may coincide with the projection of the second protective layer 52 on the second direction Y; the projection of the third pattern layer 63 on the second direction Y may coincide with the projection of the third protective layer 53 on the second direction Y; the projection of the fourth pattern layer 64 on the second direction Y may coincide with the projection of the fourth protective layer 54 on the second direction Y. Therefore, the first pattern layer 61, the second pattern layer 62, the third pattern layer 63, and the fourth pattern layer 64 provided by the present disclosure may be formed in the same process step with the first protective layer 51, the second protective layer 52, the third protective layer 53, and the fourth protective layer 54.

In an embodiment of the present disclosure, the semiconductor structure provided by the present disclosure may further include: a ninth dielectric layer 15, a tenth dielectric layer 16, and an eleventh dielectric layer 17 that are sequentially arranged on the eighth dielectric layer 14. The re-wiring through hole 41 may be located in the ninth dielectric layer 15; the re-wiring layer 42 may be located in the tenth dielectric layer 16; the passivation layer 43 may be located in the eleventh dielectric layer 17. The ninth dielectric layer 15, the tenth dielectric layer 16, and the eleventh dielectric layer 17 can project the re-wiring through hole 41 and the re-wiring layer 42.

In addition, edges of the ninth dielectric layer 15, the tenth dielectric layer 16, and the eleventh dielectric layer 17 that are close to the first dielectric layer 7 each may be in any one of the following shapes: a curve, a broken line, and a straight line. When the edges of the ninth dielectric layer 15, the tenth dielectric layer 16, and the eleventh dielectric layer 17 that are close to the first dielectric layer 7 are each in the shape of a curve, stress on the edges of the ninth dielectric layer 15, the tenth dielectric layer 16, and the eleventh dielectric layer 17 can be reduced, thereby preventing the semiconductor structure from being damaged due to excessive stress on the edges of the ninth dielectric layer 15, the tenth dielectric layer 16, and the eleventh dielectric layer 17.

In an embodiment of the present disclosure, the first dielectric layer 7, the second dielectric layer 8, the third dielectric layer 9, the fourth dielectric layer 10, the fifth dielectric layer 11, the sixth dielectric layer 12, the seventh dielectric layer 13, the eighth dielectric layer 14, the ninth dielectric layer 15, the tenth dielectric layer 16, and the eleventh dielectric layer 17 may be made of a same material. That is, all the dielectric layers may be made of silicon dioxide, but the present disclosure is not limited thereto. All the dielectric layers may alternatively be made of silicon nitride or the like, which may be configured according to actual needs, and all such materials fall within the protection scope of the present disclosure.

According to another aspect of the present disclosure, a method of manufacturing a semiconductor structure is provided. A semiconductor structure manufactured by the method of manufacturing a semiconductor structure can avoid the problem of metal residuals generate due to an excessive thickness of the semiconductor structure during cutting, thereby avoiding the problem of short circuit or discharge of the semiconductor structure in the subsequent use process. The method of manufacturing a semiconductor structure can be used for manufacturing the foregoing semiconductor structure.

Specifically, as shown in FIG. 3, the method of manufacturing a semiconductor structure provided by the present disclosure may include the following steps:

Step S10: Form a substrate 1, where the substrate 1 includes a first region 101 and a second region 102 adjacent to each other.

Step S20: Form an array structure 2 on a surface of the substrate 1, where the array structure 2 is located on the first region 101.

Step S30: Form a conductive layer 3 on a side of the array structure 2 that is away from the substrate 1, where the conductive layer 3 is electrically connected to the array structure 2.

Step S40: Form a wiring structure 4 on a side of the conductive layer 3 that is away from the array structure 2, where the wiring structure 4 may include a re-wiring through hole 41, and the re-wiring through hole 41 may be electrically connected to the conductive layer 3.

Step S50: Form a first dielectric layer 7 covering a surface of the second region 102, where a surface of the first dielectric layer 7 that is away from the substrate 1 is closer to the substrate 1, compared to a surface of the conductive layer 3 that is away from the substrate 1.

Each step is described in detail below.

As shown in FIG. 4 to FIG. 15, in step S10, a substrate 1 may be provided, and a word line structure, a bit line structure, and a shallow trench isolation structure are formed in the substrate 1. The word line structure and the bit line structure may be provided in the first region 101 of the substrate 1, so as to be electrically connected to the array structure 2. The shallow trench isolation structure may be provided in the first region 101 and/or the second region 102. However, a word line structure and a bit line structure may also be provided in the second region 102 of the substrate 1, which may be configured according to actual needs, and all such configurations fall within the protection scope of the present disclosure.

In step S20, an array structure 2 may be formed on a surface of the substrate 1, where the array structure 2 may be located on the first region 101. The array structure 2 may be electrically connected to the bit line structure and the word line structure, to receive electrical signals sent by the word line structure and the bit line structure. In an embodiment of the present disclosure, the array structure 2 may be a capacitor contact structure. However, the present disclosure is not limited thereto. The array structure 2 may further include other array elements, which may be configured according to actual needs, and all such configurations fall within the protection scope of the present disclosure.

In an embodiment of the present disclosure, a surface of the array structure 2 that is away from the substrate 1 may be farther away from the substrate 1, compared to a surface of the first dielectric layer 7 that is away from the substrate 1.

In an embodiment of the present disclosure, before the wiring structure 4 is formed on a side of the conductive layer 3 that is away from the array structure 2, the method of manufacturing a semiconductor structure may further include:

forming a protection structure 5 on the first region 101, where the protection structure 5 may be located between the array structure 2 and the first dielectric layer 7, and a surface of the protection structure 5 that is away from the substrate 1 is farther away from the substrate 1, compared to a surface of the first dielectric layer 7 that is away from the substrate 1.

The protection structure 5 includes: a plurality of protective layers arranged at intervals along a first direction X, and the protection structure 5 may at least include: a first connection layer 55, a first protective layer 51, a second connection layer 56, a second protective layer 52, a third connection layer 57, a third protective layer 53, a fourth connection layer 58, and a fourth protective layer 54 that are sequentially formed. The first connection layer 55, the first protective layer 51, the second connection layer 56, the second protective layer 52, the third connection layer 57, the third protective layer 53, the fourth connection layer 58, and the fourth protective layer 54 are arranged along the first direction X. The first connection layer 55 may be located between the first protective layer 51 and the substrate 1 to connect the first protective layer 51 and the substrate 1. The second connection layer 56 may be located between the second protective layer 52 and the first protective layer 51 to connect the second protective layer 52 and the first protective layer 51. The third connection layer 57 may be located between the third protective layer 53 and the second protective layer 52 to connect the third protective layer 53 and the second protective layer 52. The fourth connection layer 58 may be located between the fourth protective layer 54 and the third protective layer 53 to connect the fourth protective layer 54 and the third protective layer 53.

In an embodiment of the present disclosure, when the protection structure 5 is formed on the first region 101, the method of manufacturing a semiconductor structure provided by the present disclosure may further include: forming a dummy pattern group on the second region 102, where the dummy pattern group may at least include a first pattern layer 61, a second pattern layer 62, a third pattern layer 63, and a fourth pattern layer 64 that are formed in sequence. The first pattern layer 61, the second pattern layer 62, the third pattern layer 63, and the fourth pattern layer 64 may be sequentially arranged along the first direction X.

The dummy pattern group may be located between the protection structure 5 and the first dielectric layer 7, and a surface of the dummy pattern group that is away from the substrate 1 may be farther away from the substrate 1, compared to a surface of the first dielectric layer 7 that is away from the substrate 1. Moreover, the projection of each dummy pattern layer 6 on the second direction Y may overlap with the projection of one protective layer on the second direction Y. The second direction Y may be a direction pointing from the dummy pattern group to the protection structure 5.

In an embodiment of the present disclosure, the projection of each dummy pattern layer 6 on the second direction Y coincides with the projection of one protective layer on the second direction Y. That is, each dummy pattern layer 6 may be provided in a same layer with one protective layer. That is, the first pattern layer 61 may be provided in a same layer with the first protective layer 51; the second pattern layer 62 may be provided in a same layer with the second protective layer 52; the third pattern layer 63 may be provided in a same layer with the third protective layer 53; the fourth pattern layer 64 may be provided in a same layer with the fourth protective layer 54. Therefore, the dummy pattern layer 6 and the protective layer in the semiconductor structure provided by the present disclosure may be formed in the same process step.

In an embodiment of the present disclosure, the foregoing steps S30 to S50 may include:

An initial first dielectric layer 18 may be formed on the first region 101 and the second region 102 of the substrate 1. Specifically, a material of the initial first dielectric layer 18 may be deposited in the first region 101 and the second region 102 other than the array structure 2, to form the initial first dielectric layer 18. The material forming the initial first dielectric layer 18 may be silicon dioxide, but is not limited thereto. The material forming the initial first dielectric layer 18 may also be silicon nitride.

The first connection layer 55 may be formed in the initial first dielectric layer 18 on the first region 101. Specifically, the initial first dielectric layer 18 on the first region 101 may be etched to form a first through hole and a second through hole. The first through hole and the second through hole are spaced apart by a gap, and the first through hole and the second through hole may expose the surface of the substrate 1. A material forming the first connection layer 55 may be deposited in the first through hole and the second through hole, to form a first connection pillar 551 and a second connection pillar 552. The first connection pillar 551 and the second connection pillar 552 may form the first connection layer 55.

A second dielectric layer 8 may be formed on the initial first dielectric layer 18 on the first connection layer 55 and the second region 102. Specifically, a material forming the second dielectric layer 8 may be deposited on the initial first dielectric layer 18 on the first connection layer 55 and the second region 102, to form the second dielectric layer 8. The material forming the second dielectric layer 8 may be silicon dioxide, but is not limited thereto. The material forming the second dielectric layer 8 may alternatively be silicon nitride or the like.

The first protective layer 51 may be formed in the second dielectric layer 8 on the first connection layer 55, and at least one first pattern layer 61 is also formed in the second dielectric layer 8 on the second region 102. The first protective layer 51 may be electrically connected to the first connection layer 55. Moreover, when the semiconductor structure has a plurality of first pattern layers 61, the plurality of first pattern layers 61 may be arranged at intervals along a second direction Y.

Specifically, the second dielectric layer 8 on the first connection layer 55 may be etched to form a first accommodation recess, and the second dielectric layer 8 on the second region 102 is also etched to form at least one second accommodation recess. A material forming the first protective layer 51 may be filled in the first accommodation recess, and a material forming the first pattern layer 61 is filled in the second accommodation recess, to form the first protective layer 51 and at least one first pattern layer 61.

In an embodiment of the present disclosure, the material forming the first protective layer 51 and the material forming the first pattern layer 61 may be metal materials, such as tungsten, but are not limited to tungsten. Moreover, the material of the first protective layer 51 may be the same as the material of the first pattern layer 61.

A third dielectric layer 9 may be formed on the first protective layer 51, the first pattern layer 61, and the second dielectric layer 8 located on the second region 102. Specifically, a material forming the third dielectric layer 9 may be deposited on the first protective layer 51, the first pattern layer 61, and the second dielectric layer 8 located on the second region 102, to form the third dielectric layer 9. The material forming the third dielectric layer 9 may be silicon dioxide, but is not limited thereto. The material forming the third dielectric layer 9 may alternatively be silicon nitride or the like.

The second connection layer 56 may be formed in the third dielectric layer 9 on the first protective layer 51, and the second connection layer 56 may be electrically connected to the first protective layer 51. Specifically, the third dielectric layer 9 on the first protective layer 51 may be etched, to form a third through hole and a fourth through hole. The third through hole and the fourth through hole may be spaced apart by a gap, and the third through hole and the fourth through hole may expose a surface of the first protective layer 51. A material forming the second connection layer 56 may be deposited in the third through hole and the fourth through hole, to form a third connection pillar 561 and a fourth connection pillar 562. The third connection pillar 561 and the fourth connection pillar 562 may form the second connection layer 56.

In addition, a fourth dielectric layer 10 may be formed on the array structure 2, the second connection layer 56, and the third dielectric layer 9. Specifically, a material forming the fourth dielectric layer 10 may be deposited on the array structure 2, the second connection layer 56, and the third dielectric layer 9, to form the fourth dielectric layer 10. The material forming the fourth dielectric layer 10 may be silicon dioxide, but is not limited thereto. The material forming the fourth dielectric layer 10 may alternatively be silicon nitride or the like.

The second protective layer 52 may be formed in the fourth dielectric layer 10 on the second connection layer 56, and at least one second pattern layer 62 is formed in the fourth dielectric layer 10 on the second region 102. The second protective layer 52 may be electrically connected to the second connection layer 56. Moreover, when the semiconductor structure has a plurality of second pattern layers 62, the plurality of second pattern layers 62 may be arranged at intervals along the second direction Y

Specifically, the fourth dielectric layer 10 on the second connection layer 56 may be etched to form a third accommodation recess, and the fourth dielectric layer 10 on the second region 102 is also etched, to form at least one fourth accommodation recess. A material forming the second protective layer 52 may be filled in the third accommodation recess, and a material forming the second pattern layer 62 may be formed in the fourth accommodation recess, to form the second protective layer 52 and at least one second pattern layer 62.

In an embodiment of the present disclosure, the material forming the second protective layer 52 and the material forming the second pattern layer 62 may be metal materials, such as tungsten, but are not limited to tungsten. Moreover, the material of the second protective layer 52 may be the same as the material of the second pattern layer 62.

A fifth dielectric layer 11 may be formed on the second protective layer 52, the second pattern layer 62, and the fourth dielectric layer 10. Specifically, a material forming the fifth dielectric layer 11 may be deposited on the second protective layer 52, the second pattern layer 62, and the fourth dielectric layer 10, to form the fifth dielectric layer 11. The material forming the fifth dielectric layer 11 may be silicon dioxide, but is not limited thereto. The material forming the fifth dielectric layer 11 may alternatively be silicon nitride or the like.

The third connection layer 57 may be formed in the fifth dielectric layer 11 on the second protective layer 52. Specifically, the fifth dielectric layer 11 on the second protective layer 52 may be etched to form a fifth through hole and a sixth through hole. The fifth through hole and the sixth through hole may be spaced apart by a gap, and the fifth through hole and the sixth through hole may expose a surface of the second protective layer 52. A material forming the third connection layer 57 may be deposited in the fifth through hole and the sixth through hole, to form a fifth connection pillar 571 and a sixth connection pillar 572. The fifth connection pillar 571 and the sixth connection pillar 572 may form the second connection layer 56.

A sixth dielectric layer 12 may be formed on the third connection layer 57 and the fifth dielectric layer 11. Specifically, a material forming the sixth dielectric layer 12 may be deposited on the third connection layer 57 and the fifth dielectric layer 11, to form the sixth dielectric layer 12. The material forming the sixth dielectric layer 12 may be silicon dioxide, but is not limited thereto. The material forming the sixth dielectric layer 12 may alternatively be silicon nitride or the like.

The third protective layer 53 may be formed in the sixth dielectric layer 12 on the third connection layer 57, and at least one third pattern layer 63 is formed in the sixth dielectric layer 12 on the second region 102, where the third protective layer 53 may be electrically connected to the third connection layer 57. Moreover, when the semiconductor structure has a plurality of third pattern layers 63, the plurality of third pattern layers 63 may be arranged at intervals along the second direction Y.

Specifically, the sixth dielectric layer 12 on the third connection layer 57 may be etched to form a fifth accommodation recess, and the sixth dielectric layer 12 on the second region 102 may also be etched to form at least one sixth accommodation recess. A material forming the third protective layer 53 may be filled in the fifth accommodation recess, and a material forming the third pattern layer 63 may be filled in the sixth accommodation recess, to form the third protective layer 53 and at least one third pattern layer 63.

In an embodiment of the present disclosure, the material forming the third protective layer 53 and the material forming the third pattern layer 63 may be metal materials, such as tungsten, but are not limited to tungsten. Moreover, the material of the third protective layer 53 may be the same as the material of the third pattern layer 63.

A seventh dielectric layer 13 may be formed on the third protective layer 53, the third pattern layer 63, and the sixth dielectric layer 12. Specifically, a material forming the seventh dielectric layer 13 may be deposited on the third protective layer 53, the third pattern layer 63, and the sixth dielectric layer 12, to form the seventh dielectric layer 13. The material forming the seventh dielectric layer 13 may be silicon dioxide, but is not limited thereto. The material forming the seventh dielectric layer 13 may alternatively be silicon nitride or the like.

The fourth connection layer 58 may be formed in the seventh dielectric layer 13 on the third protective layer 53. Specifically, the seventh dielectric layer 13 on the third protective layer 53 may be etched to form a seventh through hole and an eighth through hole. The seventh through hole and the eighth through hole may be spaced apart by a gap, and the seventh through hole and the eighth through hole may expose a surface of the third protective layer 53. A material forming the fourth connection layer 58 may be deposited in the seventh through hole and the eighth through hole, to form a seventh connection pillar 581 and an eighth connection pillar 582. The seventh connection pillar 581 and the eighth connection pillar 582 may form the second connection layer 56.

In an embodiment of the present disclosure, the first connection layer 55 and the second connection layer 56 may be arranged in a staggered manner; the second connection layer 56 and the third connection layer 57 may be arranged in a staggered manner; the third connection layer 57 and the fourth connection layer 58 may be arranged in a staggered manner.

That is, a projection of the third connection pillar 561 of the second connection layer 56 on the substrate 1 may be located between projections of the first connection pillar 551 and the second connection pillar 552 on the substrate 1. Moreover, the projection of the second connection pillar 552 of the first connection layer 55 on the substrate 1 may be located between projections of the third connection pillar 561 and the fourth connection pillar 562 on the substrate 1. A projection of the sixth connection pillar 572 of the third connection layer 57 on the substrate 1 may be located between projections of the third connection pillar 561 and the fourth connection pillar 562 on the substrate 1, and the projection of the sixth connection pillar 572 on the substrate 1 may be located between projections of the seventh connection pillar 581 and the eighth connection pillar 582 on the substrate 1. The projection of the seventh connection pillar 581 of the fourth connection layer 58 on the substrate 1 may be located between projections of the fifth connection pillar 571 and the sixth connection pillar 572 on the substrate 1.

In addition, an eighth dielectric layer 14 may be formed on the fourth connection layer 58 and the seventh dielectric layer 13. Specifically, a material forming the eighth dielectric layer 14 may be deposited on the fourth connection layer 58 and the seventh dielectric layer 13, to form the eighth dielectric layer 14. The material forming the eighth dielectric layer 14 may be silicon dioxide, but is not limited thereto. The material forming the eighth dielectric layer 14 may alternatively be silicon nitride or the like.

The fourth protective layer 54 may be formed in the eighth dielectric layer 14 on the fourth connection layer 58, and the conductive layer 3 is formed in the eighth dielectric layer 14 on the first region 101; moreover, at least one fourth pattern layer 64 is formed in the eighth dielectric layer 14 on the second region 102. The fourth protective layer 54 may be electrically connected to the fourth connection layer 58.

Specifically, the eighth dielectric layer 14 on the fourth connection layer 58 may be etched to form a seventh accommodation recess, and the eighth dielectric layer 14 on the first region 101 may be etched to form the eighth accommodation recess; moreover, the eighth dielectric layer 14 on the second region 102 may be etched to form at least one ninth accommodation recess. A material forming the fourth protective layer 54 may be filled in the seventh accommodation recess, a material forming the conductive layer 3 may be filled in the seventh accommodation recess, and a material forming the fourth pattern layer 64 may be filled in the eighth accommodation recess, to form the fourth protective layer 54 and at least one fourth pattern layer 64.

In an embodiment of the present disclosure, the material forming the fourth protective layer 54, the material forming the conductive layer 3, and the material forming the third pattern layer 63 may be metal materials, such as tungsten, but are not limited to tungsten. Moreover, the material of the third protective layer 53 and the material of the conductive layer 3 may be the same as the material of the third pattern layer 63.

In addition, a ninth dielectric layer 15 may further be formed on the conductive layer 3, the fourth protective layer 54, the fourth pattern layer 64, and the eighth dielectric layer 14. Specifically, a material forming the ninth dielectric layer 15 may be deposited on the conductive layer 3, the fourth protective layer 54, the fourth pattern layer 64, and the eighth dielectric layer 14, to form the ninth dielectric layer 15. The material forming the ninth dielectric layer 15 may be silicon dioxide, but is not limited thereto. The material forming the ninth dielectric layer 15 may alternatively be silicon nitride or the like.

The re-wiring through hole 41 is formed in the ninth dielectric layer 15 on the first region 101. Meanwhile, a part of the ninth dielectric layer 15 on the conductive layer 3, a part of the ninth dielectric layer 15 on the second region 102, a part of the eighth dielectric layer 14 on the second region 102, a part of the seventh dielectric layer 13 on the second region 102, a part of the sixth dielectric layer 12 on the second region 102, a part of the fifth dielectric layer 11 on the second region 102, a part of the fourth dielectric layer 10 on the second region 102, a part of the third dielectric layer 9 on the second region 102, a part of the second dielectric layer 8 on the second region 102, a part of the initial first dielectric layer 18 on the second region 102, and at least a part of the dummy pattern group on the second region 102 are removed, and the remaining initial first dielectric layer 18 on the second region 102 forms the first dielectric layer 7. A surface of the first dielectric layer 7 that is away from the substrate 1 is closer to the substrate 1, compared to a surface of the first protective layer 51 that is away from the substrate 1.

Specifically, the ninth dielectric layer 15 on the first region 101 may be etched to form a tenth accommodation recess, and a material forming the re-wiring through hole 41 may be filled in the tenth accommodation recess, to form the re-wiring through hole 41. Moreover, during etching of the ninth dielectric layer 15 on the first region 101, a part of the ninth dielectric layer 15, which is close to the second region 102, on the first region 101, a part of the eighth dielectric layer 14 on the second region 102, a part of the seventh dielectric layer 13 on the second region 102, a part of the sixth dielectric layer 12 on the second region 102, a part of the fifth dielectric layer 11 on the second region 102, a part of the fourth dielectric layer 10 on the second region 102, a part of the third dielectric layer 9 on the second region 102, a part of the second dielectric layer 8 on the second region 102, a part of the initial first dielectric layer 18 on the second region 102, and at least a part of the dummy pattern group on the second region 102 are etched simultaneously.

Moreover, as shown in FIG. 1, when a part of the dummy pattern group is removed, the first dielectric layer 7 and partial dummy pattern group on the first dielectric layer 7 may remain on the second region 102; as shown in FIG. 2, when the dummy pattern group is completely removed, only the first dielectric layer 7 remains on the second region 102.

In an embodiment of the present disclosure, a thickness of the first dielectric layer 7 may alternatively be less than a distance between the first protective layer 51 and the substrate 1.

The foregoing steps S30 to S50 may further include the following step:

A tenth dielectric layer 16 may be formed on the ninth dielectric layer 15, the re-wiring through hole 41, and the first dielectric layer 7. Specifically, a material forming the tenth dielectric layer 16 may be deposited on the ninth dielectric layer 15, the re-wiring through hole 41, and the first dielectric layer 7, to form the tenth dielectric layer 16. The material forming the tenth dielectric layer 16 may be silicon dioxide, but is not limited thereto. The material forming the tenth dielectric layer 16 may alternatively be silicon nitride or the like.

A re-wiring layer 42 may be formed in the tenth dielectric layer 16 on the first region 101. Specifically, the tenth dielectric layer 16 on the first region 101 may be etched to form an eleventh accommodation recess. A material forming the re-wiring layer 42 may be filled in the eleventh accommodation recess, to produce the re-wiring layer 42.

In addition, an eleventh dielectric layer 17 may be formed on the re-wiring layer 42 and the tenth dielectric layer 16. Specifically, the material forming the eleventh dielectric layer 17 may be deposited on the re-wiring layer 42 and the tenth dielectric layer 16, to form the eleventh dielectric layer 17. The material forming the eleventh dielectric layer 17 may be silicon dioxide, but is not limited thereto. The material forming the eleventh dielectric layer 17 may alternatively be silicon nitride or the like.

A passivation layer 43 may be formed on the eleventh dielectric layer 17 of the first region 101; meanwhile, the tenth dielectric layer 16 and the eleventh dielectric layer 17 that are on the first dielectric layer 7 are removed. Specifically, the eleventh dielectric layer 17 on the first region 101 may be etched to form an opening 44 on the re-wiring layer 42, and the remaining eleventh dielectric layer 17 on the first region 101 is the passivation layer 43. Moreover, during etching of the eleventh dielectric layer 17, the tenth dielectric layer 16 and the eleventh dielectric layer 17 on the first dielectric layer 7 may be etched at the same time, to remove the tenth dielectric layer 16 and the eleventh dielectric layer 17, so that only the first dielectric layer 7 is retained.

In an embodiment of the present disclosure, edges of the remaining ninth dielectric layer 15, tenth dielectric layer 16, and eleventh dielectric layer 17 that are close to the first dielectric layer 7 each may be in any one of the following shapes: a curve, a broken line, and a straight line.

In an embodiment of the present disclosure, the first dielectric layer 7, the second dielectric layer 8, the third dielectric layer 9, the fourth dielectric layer 10, the fifth dielectric layer 11, the sixth dielectric layer 12, the seventh dielectric layer 13, the eighth dielectric layer 14, the ninth dielectric layer 15, the tenth dielectric layer 16, and the eleventh dielectric layer 17 may be made of a same material. That is, all the dielectric layers may be made of silicon dioxide, but the present disclosure is not limited thereto. All the dielectric layers may alternatively be made of silicon nitride or the like, which may be configured according to actual needs, and all such materials fall within the protection scope of the present disclosure.

In addition, it should be noted that, any steps performed simultaneously or synchronously described above may be performed separately or one after another, which may be configured according to actual needs, and all such configurations fall within the protection scope of the present disclosure.

Moreover, it should be further noted that, for the structural relationships between elements or layers in the method of manufacturing a semiconductor structure, reference may be made to the foregoing semiconductor structure, and details are not described in the method of manufacturing a semiconductor structure again.

Those skilled in the art may easily figure out other implementations of the present disclosure after considering the specification and practicing the present disclosure disclosed herein. The present disclosure is intended to cover any variations, purposes or applicable changes of the present disclosure. Such variations, purposes or applicable changes follow the general principle of the present disclosure and include common knowledge or conventional technical means in the technical field which is not disclosed in the present disclosure. The specification and embodiments are merely considered as illustrative, and the real scope and spirit of the present disclosure are pointed out by the claims.

1. A semiconductor structure, wherein the semiconductor structure comprises:
a substrate, comprising a first region and a second region that are adjacent to each other;
an array structure, located on a surface of the substrate and on the first region;
a conductive layer, located on a side of the array structure that is away from the substrate, and electrically connected to the array structure;
a wiring structure, located on a side of the conductive layer that is away from the array structure, wherein the wiring structure comprises a re-wiring through hole, and the re-wiring through hole is electrically connected to the conductive layer; and
a first dielectric layer, covering a surface of the second region of the substrate, wherein a surface of the first dielectric layer that is away from the substrate is closer to the substrate, compared to a surface of the conductive layer that is away from the substrate.

2. The semiconductor structure according to claim 1, wherein the semiconductor structure further comprises:
a protection structure, located on the first region and between the array structure and the first dielectric layer, wherein a surface of the protection structure that is away from the substrate is farther away from the substrate, compared to a surface of the first dielectric layer that is away from the substrate.

3. The semiconductor structure according to claim 2, wherein a distance between the substrate and the surface of the protection structure that is away from the substrate is the same as a distance between the substrate and the surface of the conductive layer that is away from the substrate.

4. The semiconductor structure according to claim 3, wherein the protection structure comprises:
a plurality of protective layers, arranged at intervals along a first direction, wherein adjacent ones of the protective layers are connected to each other;
wherein the first direction is a direction pointing from the substrate to the array structure.

5. The semiconductor structure according to claim 4, wherein the protection structure at least comprises: a first protective layer, a second protective layer, a third protective layer, and a fourth protective layer that are arranged at intervals along the first direction; and
the semiconductor structure further comprises:
a second dielectric layer, a third dielectric layer, a fourth dielectric layer, a fifth dielectric layer, a sixth dielectric layer, a seventh dielectric layer, and an eighth dielectric layer that are sequentially formed on the first region along the first direction, wherein the first protective layer is located in the second dielectric layer, the second protective layer is located in the fourth dielectric layer, the third protective layer is located in the sixth dielectric layer, and the fourth protective layer is located in the eighth dielectric layer.

6. The semiconductor structure according to claim 5, wherein the wiring structure further comprises:
a re-wiring layer, located on a side of the re-wiring through hole that is away from the substrate; and
a passivation layer, located on a side of the re-wiring layer that is away from the substrate.

7. The semiconductor structure according to claim 5, wherein the semiconductor structure further comprises:
a dummy pattern group, located between the protection structure and the first dielectric layer, wherein a surface of the dummy pattern group that is away from the substrate is farther away from the substrate, compared to the surface of the first dielectric layer that is away from the substrate.

8. The semiconductor structure according to claim 7, wherein the dummy pattern group comprises:
a plurality of dummy pattern layers, arranged at intervals along the first direction, wherein a projection of each of the plurality of dummy pattern layers on a second direction overlaps with a projection of one of the protective layers on the second direction;
wherein the second direction is a direction pointing from the dummy pattern group to the protection structure.

9. The semiconductor structure according to claim 8, wherein the projection of each of the dummy pattern layers on the second direction coincides with the projection of one of the protective layers on the second direction.

10. The semiconductor structure according to claim 8, wherein a part of the second region is also provided with the second dielectric layer, the third dielectric layer, the fourth dielectric layer, the fifth dielectric layer, the sixth dielectric layer, the seventh dielectric layer, and the eighth dielectric layer; and
the dummy pattern group at least comprises: a first pattern layer, a second pattern layer, a third pattern layer, and a fourth pattern layer; the first pattern layer is located in the second dielectric layer on the second region, the second pattern layer is located in the fourth dielectric layer on the second region, the third pattern layer is located in the sixth dielectric layer on the second region, and the fourth pattern layer is located in the eighth dielectric layer on the second region.

11. The semiconductor structure according to claim 6, wherein the semiconductor structure further comprises: a ninth dielectric layer, a tenth dielectric layer, and an eleventh dielectric layer that are sequentially formed on the eighth dielectric layer; the re-wiring through hole is located in the ninth dielectric layer, the re-wiring layer is located in the tenth dielectric layer, and the passivation layer is located in the eleventh dielectric layer; and
edges of the ninth dielectric layer, the tenth dielectric layer, and the eleventh dielectric layer that are close to the first dielectric layer are each in any one of the following shapes: a curve, a broken line, and a straight line.

12. The semiconductor structure according to claim 1, wherein a thickness of the first dielectric layer is greater than or equal to 10 nm.

13. A method of manufacturing a semiconductor structure, comprising:
forming a substrate, wherein the substrate comprises a first region and a second region that are adjacent to each other;
forming an array structure on a surface of the substrate, wherein the array structure is located on the first region;
forming a conductive layer on a side of the array structure that is away from the substrate, wherein the conductive layer is electrically connected to the array structure;
forming a wiring structure on a side of the conductive layer that is away from the array structure, wherein the wiring structure comprises a re-wiring through hole, and the re-wiring through hole is electrically connected to the conductive layer; and
forming a first dielectric layer covering a surface of the second region, wherein a surface of the first dielectric layer that is away from the substrate is closer to the substrate, compared to a surface of the conductive layer that is away from the substrate.

14. The method of manufacturing a semiconductor structure according to claim 13, before the forming a wiring structure on a side of the conductive layer that is away from the array structure, further comprising:
forming a protection structure on the first region, wherein the protection structure is between the array structure and the first dielectric layer, and a surface of the protection structure that is away from the substrate is farther away from the substrate, compared to a surface of the first dielectric layer that is away from the substrate.

15. The method of manufacturing a semiconductor structure according to claim 14, wherein the protection structure at least comprises: a first connection layer, a first protective layer, a second connection layer, a second protective layer, a third connection layer, a third protective layer, a fourth connection layer, and a fourth protective layer that are formed in sequence.

16. The method of manufacturing a semiconductor structure according to claim 15, wherein the protection structure is formed on the first region, and the method of manufacturing a semiconductor structure further comprises:
forming a dummy pattern group on the second region, wherein the dummy pattern group at least comprises a first pattern layer, a second pattern layer, a third pattern layer, and a fourth pattern layer that are formed in sequence.

17. The method of manufacturing a semiconductor structure according to claim 16, wherein the array structure is formed on a surface of the substrate, and the method of manufacturing a semiconductor structure further comprises:
forming an initial first dielectric layer on the first region and on the second region;
forming the first connection layer in the initial first dielectric layer on the first region;
forming a second dielectric layer on the first connection layer and on the initial first dielectric layer that is located on the second region;
forming the first protective layer in the second dielectric layer on the first connection layer, and forming at least one first pattern layer in the second dielectric layer on the second region, wherein the first protective layer is electrically connected to the first connection layer;
forming a third dielectric layer on the first protective layer, on the first pattern layer, and on the second dielectric layer that is located on the second region; and
forming the second connection layer in the third dielectric layer on the first protective layer, wherein the second connection layer is electrically connected to the first protective layer.

18. The method of manufacturing a semiconductor structure according to claim 17, wherein
forming a fourth dielectric layer on the array structure, on the second connection layer, on and the third dielectric layer;
forming the second protective layer in the fourth dielectric layer on the second connection layer, and forming at least one second pattern layer in the fourth dielectric layer on the second region, wherein the second protective layer is electrically connected to the second connection layer;
forming a fifth dielectric layer on the second protective layer, on the second pattern layer, and on the fourth dielectric layer;
forming the third connection layer in the fifth dielectric layer on the second protective layer;
forming a sixth dielectric layer on the third connection layer and on the fifth dielectric layer;
forming the third protective layer in the sixth dielectric layer on the third connection layer, and forming at least one third pattern layer in the sixth dielectric layer on the second region, wherein the third protective layer is electrically connected to the third connection layer;
forming a seventh dielectric layer on the third protective layer, on the third pattern layer, and on the sixth dielectric layer;
forming the fourth connection layer in the seventh dielectric layer on the third protective layer;
forming an eighth dielectric layer on the fourth connection layer and on the seventh dielectric layer; and
forming the fourth protective layer in the eighth dielectric layer on the fourth connection layer, forming the conductive layer in the eighth dielectric layer on the first region, and forming at least one fourth pattern layer in the eighth dielectric layer on the second region, wherein the fourth protective layer is electrically connected to the fourth connection layer.

19. The method of manufacturing a semiconductor structure according to claim 18, wherein
forming a ninth dielectric layer on the conductive layer, on the fourth protective layer, on the fourth pattern layer, and on the eighth dielectric layer; and
forming the re-wiring through hole in the ninth dielectric layer on the first region; and
removing a part of the ninth dielectric layer on the conductive layer, a part of the ninth dielectric layer on the second region, a part of the eighth dielectric layer on the second region, a part of the seventh dielectric layer on the second region, a part of the sixth dielectric layer on the second region, a part of the fifth dielectric layer on the second region, a part of the fourth dielectric layer on the second region, a part of the third dielectric layer on the second region, a part of the second dielectric layer on the second region, a part of the initial first dielectric layer on the second region, and at least a part of the dummy pattern group on the second region; wherein a remaining initial first dielectric layer on the second region forms the first dielectric layer, and a surface of the first dielectric layer that is away from the substrate is closer to the substrate, compared to a surface of the first protective layer that is away from the substrate.

20. The method of manufacturing a semiconductor structure according to claim 19, further comprising: forming a tenth dielectric layer on the ninth dielectric layer, on the re-wiring through hole, and on the first dielectric layer;
forming a re-wiring layer in the tenth dielectric layer on the first region;
forming an eleventh dielectric layer on the re-wiring layer and on the tenth dielectric layer; and
forming a passivation layer on the eleventh dielectric layer on the first region, and removing the tenth dielectric layer and the eleventh dielectric layer that are located on the first dielectric layer;
wherein the first dielectric layer, the second dielectric layer, the third dielectric layer, the fourth dielectric layer, the fifth dielectric layer, the sixth dielectric layer, the seventh dielectric layer, the eighth dielectric layer, the ninth dielectric layer, the tenth dielectric layer, and the eleventh dielectric layer are made of a same material.
